(19) United States
(12) Patent Application Publication
(10) Pub. No.: US 2009/0147612 A1
(43) Pub. Date: Jun. 11, 2009

(54) SYSTEM FOR CONTROLLING MEMORY POWER CONSUMPTION IN INTEGRATED DEVICES

(75) Inventor: Paul E. McKenney, Beaverton, OR (US)

Correspondence Address: CANTOR COLBURN LLP - IBM TUSCON DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/951,440

(22) Filed: Dec. 6, 2007

(51) Int. Cl. G11C 5/14

(52) U.S. Cl. 365/227

(57) ABSTRACT

A method for reducing power consumption in integrated devices is provided. The method comprising: locating a plurality of unused blocks of memory and a plurality of used blocks of memory in a memory device tlhrough a tracking mechanism; performing a refresh operation on the plurality of used blocks of memory at a constant frequency and suppressing the refresh operation on the plurality of unused blocks of memory through a memory controller; and suppressing error correction codes or parity errors on at least one of the plurality of unused blocks of memory when the at least one of the plurality of unused blocks of memory is accessed through the memory controller.

### BACKGROUND OF THE INVENTION

1. Field of the Invention

This invention relates to a computer system, and more particularly a computer system configured for implementing a method for reducing power consumption in integrated devices.

2. Description of Background

Current methods of powering down unused memory are extremely coarse grained, usually requiring software to evacuate all data from a memory unit that holds a large fraction of the memory in the system. Such evacuation can be extremely complex or even infeasible, particular in presence of high-speed devices that require dedicated receive buffers. Resetting such devices in order to relocate such receive buffers can cause data loss due to receive or violation of communications latency constraints. In addition, in systems with interleaved memory, powering down a memory bank may adversely affect performance, which in turn can increase per-unit-work power consumption due to longer wait times for memory access. In addition, powering off a bank of memory is a heavyweight operation, so prediction of future usage is required.

### SUMMARY OF THE INVENTION

The shortcomings of the prior art are overcome and additional advantages are provided through the provision of method for reducing power consumption in integrated devices, the method comprising: locating a plurality of unused blocks of memory and a plurality of used blocks of memory in a memory device through a tracking mechanism; performing a refresh operation on the plurality of used blocks of memory at a constant frequency and suppressing the refresh operation on the plurality of unused blocks of memory through a memory controller; and suppressing error correction codes or parity errors on at least one of the plurality of unused blocks of memory when the at least one of the plurality of unused blocks of memory is accessed through the memory controller.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution for implementing a method for reducing power consumption in integrated devices.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction With the accompanying drawings in which:

FIG. 1 illustrates a schematic diagram of a computer system in accordance with one exemplary embodiment of the present invention;

FIG. 2 illustrates a schematic diagram of a dynamic random access memory of the computer system in electrical communication with a power source in accordance with one exemplary embodiment of the present invention;

FIG. 3 illustrates a schematic diagram of the dynamic access memory having used blocks of memory being refreshed by the power source while unused blocks of memory are being suppressed the refresh in accordance with one exemplary embodiment of the present invention;

FIG. 4 illustrates a data flow diagram of a computer system for implementing a method for reducing power consumption in integrated devices in accordance with one exemplary embodiment of the present invention; and

FIG. 5 illustrates another data flow diagram of the computer system implementing a method of suppressing and re-enabling error correction codes or parity errors on at least one of the unused blocks of memory when the at least one of unused blocks of memory is accessed.

The detailed description explains the preferred embodiments of the inventions together with advantages and features, by way of example with reference to the drawings.

### DETAILED DESCRIPTION OF THE INVENTION

Exemplary embodiments of a computer system and method for reducing power consumption in integrated devices in accordance with the present invention will now be described with reference to the drawings. The exemplary computer system described herein is configured to locate a plurality of unused blocks of memory and a plurality of used blocks of memory in a memory device through a tracking mechanism. The exemplary computer system described herein is also configured to perform a refresh operation on the plurality of used blocks of memory and suppress the refresh operation on the plurality of unused blocks of memory through a memory controller. The exemplary computer system described herein is also configured to suppress error correction codes or parity errors on at least one of the plurality of unused blocks of memory when the at least one of the plurality of unused blocks of memory is accessed through a memory controller. Furthermore, the exemplary computer system described herein is configured to initialize at least one of the plurality of unused blocks of memory being accessed by performing a refresh operation on the at least one of the plurality of unused blocks of memory being accessed and mark the at least one of the plurality of unused blocks of memory being accessed as one of the plurality of used blocks of memory through the memory controller. Optionally, the exemplary computer system described herein is configured to re-enable error corrections codes or parity errors on the at least one of the plurality of unused blocks of memory.

The inventors herein have recognized that selectively suppressing refresh cycles over unused blocks of memory in a memory device will reduce overall power consumption in the same. The reason is that for memory blocks of dynamic random access memory (DRAM) that are not in use or in service, a major component of power consumption will be the refresh cycles that are performed on such blocks in order for the same to retain data.

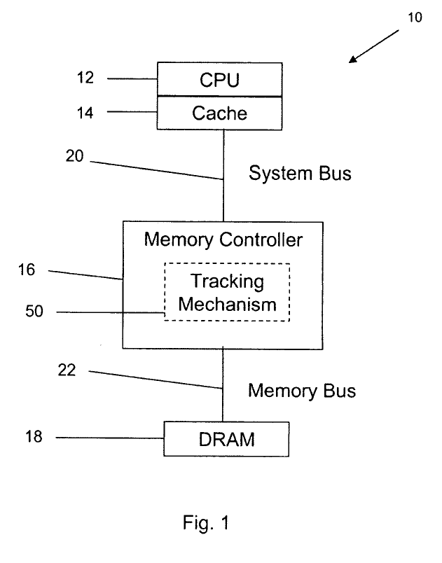

For a better understanding of the invention and its operation, turning now to the drawings, FIG. 1 illustrates a simplified schematic of a computer system 10 in accordance with exemplary embodiments of the present invention. The system 10 includes a control processing unit (CPU) 12, a cache memory 14, a memory controller 16, and a DRAM 18. The system 10 further includes a tracking mechanism 50 as shown and will later be discussed in detail below. The cache 14 is in signal communication with the memory controller 16 via a system bus 20. The memory controller 16 is in signal communication with the DRAM 18 via a memory bus 22.

In accordance with one exemplary embodiment, the CPU 12 operably communicates with DRAM 18. More specifically, the CPU 12 selectively executes instructions by fetching both instructions and referenced data from memory device 18 via cache memory 14 and memory controller 16. The CPU 12 can be any conventional processing unit configured for carrying out the methods and/or functions described herein. In one exemplary embodiment, the CPU 12 comprises a combination of hardware and/or software/firm ware with as computer program that, when loaded and executed, permits the CPU 12 to operate such that it carries out the methods described herein.

Computer program means or computer program used in the present context of exemplary embodiments of the present invention include any expression, in any language, code, notation, or the like of a set of instructions intended to cause a system having information processing capabilities to perform a particular function either directly or after conversion to another language, code, notation, or the like, reproduction in a different material form.

In accordance with one exemplary embodiment, the cache memory 14 is in signal communication with CPU 12 and may be any conventional storage device for storing data in which the CPU 12 selectively accesses. The cache memory 14 is also in signal communication with the memory controller 16 via system bus 20. In one exemplary embodiment, the cache memory 14 is controlled by CPU 12 to selectively store data retrieved from DRAM 18.

In accordance with one exemplary embodiment, the memory controller 16 is in signal communication with both cache memory 14 and DRAM 18 via system bus 20 and memory bus 22 respectively. In one exemplary embodiment, the memory controller 16 is configured for performing a refresh operation on the memory device, which will be described in more detail below. However, it is contemplated in other exemplary embodiments of the present invention that the CPU 12 performs the refresh operation, by a computer program running periodically on the CPU 12, by external hardware, or a combination of both.

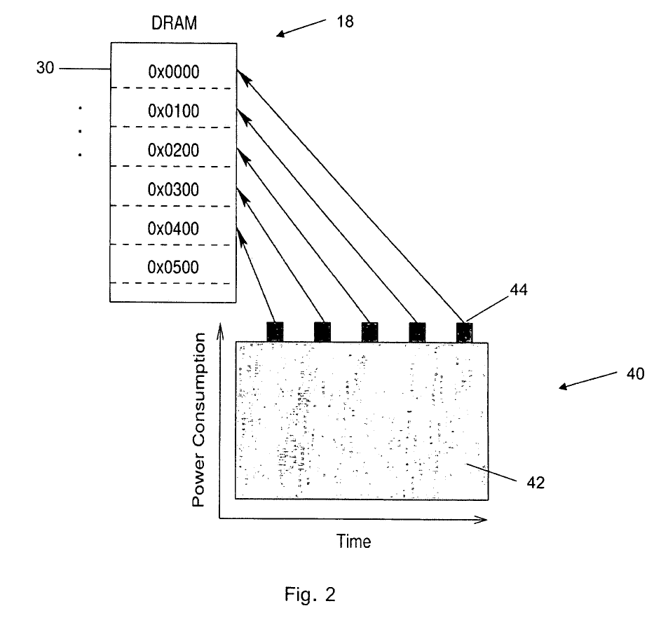

Now referring to FIG. 2, DRAM 18 includes a plurality of blocks of memory 30 each having cells (not shown) disposed therein in accordance with one exemplary embodiment. The cells within each of the blocks of memory 30 are organized in rows and columns and correspondingly multiple word lines and bit lines (M word lines×N bit lines). For example, one block of memory 30 includes cells beginning at address 0x000, another block of memory 30 includes cells beginning at address 0x0110, another block of memory 30 includes cells beginning at address 0x0200, and so forth as shown in FIG. 2. Each of the cells disposed in each block contains a stored bit of data (logical “1” RUORgIFDO“0”). 6uFK GDDLV retained within its respective cell only for a limited amount of time unless the capacitor charge in the cell is maintained at an operating level. As such, the cells within each block of memory 30 in DRAM 18 need to be refreshed periodically or data will be lost. In accordance with one non-limiting exemplary embodiment, the blocks of memory 30 are divided so that each block of memory includes one row of cells disposed in DRAM 18. As such, the memory controller 16 refreshes one entire row at a time. Of course, each block of memory may include more than one row of cells disposed in DRAM 18 and should not be limited to the configuration shown.

The DRAM 18 can be any conventional DRAM 18 for storing bits of data. Each cell within each block of memory 30 includes a capacitor (not shown) for holding charge, which allows the data within each cell to be retained therein. The capacitor of each cell; however, requires its capacitor charge to refresh or charge back up periodically. This is accomplished through the refresh operation performed by the memory controller 16.

The DRAM 18 is coupled to a power source, which is represented by an exemplary power diagram 40. The CPU 12, cache memory 14, and memory controller 16 are also coupled to the power source in accordance with one exemplary embodiment. Of course, the computer system 10 may comprise of more than one power source for correspondingly powering up the various components (memory controller). As illustrated through power diagram 40, the power source provides charge to each block of memory 30 of DRAM 18 during the refresh operation and steady-state power to enable the DRAM 18 and memory controller 16 to be ready to respond to requests from the CPU 12. The power diagram 40 illustrates the power consumption of DRAM 18 over time. The steady-state power consumed by DRAM 18 is indicated by area 42 of the power diagram 40. Area 42 is representative of the amount of steady-state power consumed by DRAM 18 over time. The power consumed by the periodic refresh operations over time is indicated by area 44 of the power diagram 40. Area 44 is representative of the amount of additional power consumed by each block of memory 30 of DRAM 18 over a particular period of time or during a refresh interval. It should be understood that area 42 and 44 are not to scale and that the relative sizes vary depending on the size of the memory and design of the computer system.

In accordance with one exemplary embodiment, the memory controller 16 includes a means for locating blocks of memory 30 within DRAM 18 that are not being used or in service, hereinafter referred to as unused blocks of memory, and locating blocks of memory 30 within DRAM 18 that are being used or in service, hereinafter referred to as used blocks of memory. In one non-limiting exemplary embodiment, the means for locating unused blocks of memory and used blocks of memory within DRAM 18 includes a tracking mechanism 50 (FIG. 1) configured for tracking or locating unused blocks of memory and used blocks of memory through the use of bit vectors, numerical address ranges, hardware registers, or the like. Of course, the tracking mechanism 50 could comprise of various types of hardware and/or software configured for carrying out the methods and operations described herein. It is contemplated that the tracking mechanism 50 is a separate component from the memory controller 16 and is in signal communication with the same. As such, it contemplated that additional hardware and/or software is incorporated for providing signal communication between the memory controller 16 and the tracking mechanism 50.

It is further contemplated in other exemplary embodiments of the present invention that the tracking mechanism 32 is part of the CPU 12 and controlled by the same. In other words, the means for locating unused blocks of memory and used blocks of memory within DRAM is located within or programed to CPU 12 or operably communicates with the same using additional hardware and/or software in accordance with exemplary embodiments of the present invention.

In accordance with one exemplary embodiment, the memory controller 16 includes a means for controlling the refresh operation, which comprises of one or a combination of hardware and software/firmware technology. In one non-limiting exemplary embodiment, the means includes a computer program configured for enabling the memory controller 16 to maintain a dynamically updated data structure of the DRAM 18 to determine what locations are refreshed. This can be a dense-array list of locations, where entries are deleted by copying the final entry to overwrite the entry to be removed, and where entries are added at the end, terminated either with a special sentinel entry or via a list length, via a bit vector, or via any number of data structures well known to those skilled in the art. In accordance with one non-limiting exemplary embodiment, the refresh operation is carried out at a constant frequency so that if the list is short, a smaller fraction of CPU time is consumed refreshing. In another non-limiting exemplary embodiment, the means includes the use of a hypervisor, which is a well-known virtualized software product configured for permitting idle guest operation systems to use zero power consumption or processing and is further configured for providing additional memory mapping capabilities. In accordance with another non-limiting exemplary embodiment, the means includes a hardware means (e.g., dense array of blocks, bit vector, or the like) to guide hardware refresh. To attain power savings, the hardware refresh sequencing would start through the list or each row within the memory device at a constant frequency regardless of the length of the list. As such, a given block of memory would be refreshed at a constant rate. In the foregoing exemplary embodiments, it should be understood that additional hardware and/or software/firmware technologies could be used to carry out the methods and/or functions described above.

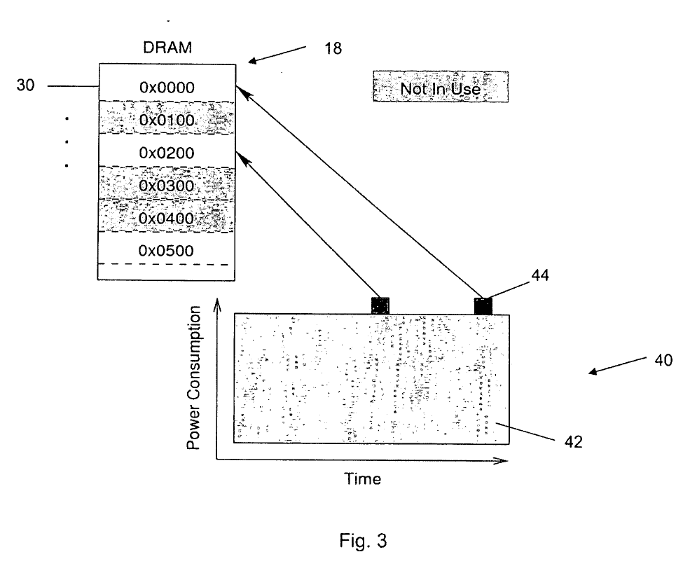

Turning now to FIG. 3 illustrating the current methods of refreshing the used blocks of memory and suppressing refresh over unused blocks of memory in DRAM 18 as described herein. In operation, the tracking mechanism 50 of memory controller 16 locates the used blocks of memory and the unused blocks of memory in DRAM 18. Then, the memory controller 16 performs the refresh operation only on the used blocks of memory and suppresses the refresh operation on the unused blocks of memory. For example, as shown in FIG. 3, the blocks of memory correspondingly located at addresses 0x0000, 0x0200, and 0x0500 are designated as used blocks of memory. Each of these used blocks of memory is refreshed with charge by the power source. In this example, the blocks of memory correspondingly located at addresses 0x0100, 0x0300, and 0x0400 are designated as unused blocks of memory. The refresh operation is suppressed for each of these unused blocks of memory. Advantageously, a power-conservation measure is realized by suppressing the refresh operation on unused blocks of memory.

In accordance with one exemplary embodiment, the refresh operation on the block at address 0x0200 and then to the block at address 0x0500 is carried out at a constant frequency. Thus, for example, when the used blocks of memory only comprise of the block at address 0x0000 and the block at address 0x0200, then a smaller fraction of CPU time is consumed refreshing. The refresh operation is performed one block at a time during a refresh interval in accordance with one exemplary embodiment.

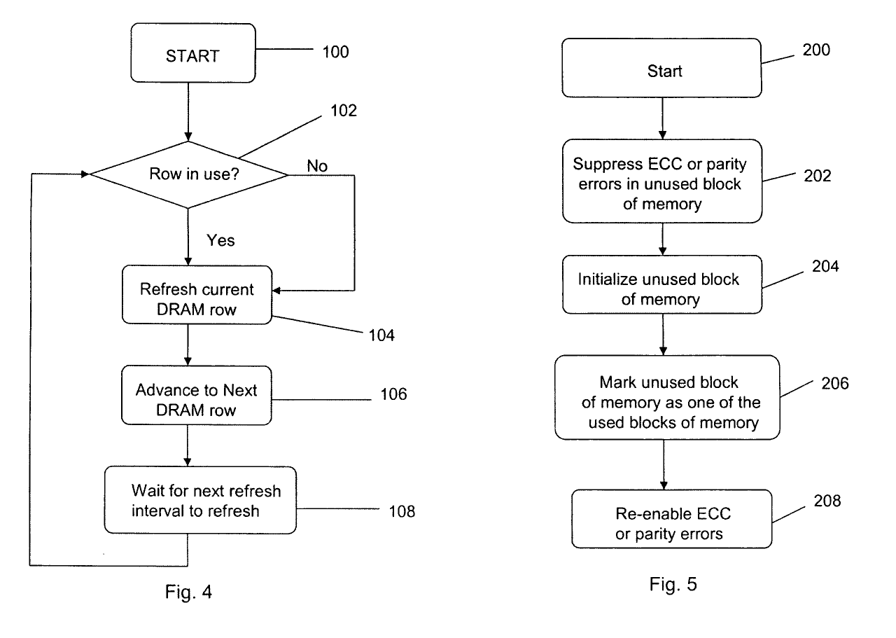

In accordance with an exemplary embodiment of the present invention, an exemplary method for reducing power consumption in a DRAM is provided and illustrated in FIG. 4. In this exemplary method, initialize operation at block 100. Then, determine if the block of memory in the DRAM is in use in block 102. This is determined through tracking mechanism 50 in accordance with one exemplary embodiment. If the answer in block 102 is yes, then refresh the block of memory in block 104. If the answer in block 102 is no, then advance to the next block of memory in the DRAM in block 106. Next, wait for the next refresh interval to refresh at block 108. The operations in blocks 102-108 are performed for each block of memory in the DRAM.

In accordance with an exemplary embodiment of the present invention, the computer system 10 has conventional error correction code (ECC) or parity protection. Consequently, the unused blocks of memory accumulate various known errors such as ECC or parity code errors, when the unused blocks of memory remain unused or unrefreshed for a certain period of time. As such, subsequent accesses to the unused blocks of memory can result in ECC or parity errors, which can result in application failure or system crashes. In one exemplary embodiment of the present invention, the memory controller 16 includes a means for suppressing or ignoring ECC or parity errors on the unused blocks of memory when subsequently accessed, initializing the same by performing a refresh operation on the unused blocks of memory that are subsequently accessed, and marking the unused blocks of memory subsequently accessed as used blocks of memory. Optionally, the aforementioned means of the memory controller 16 further re-enables ECC or parity error. In accordance with one non-limiting exemplary embodiment, the aforementioned means of the memory controller 16 includes hardware resisters. Of course, the aforementioned means of the memory controller 16 could comprise of various types of hardware and/or software configured for carrying out the methods and operations described above.

The method described above is simplified in the exemplary method provided and illustrated in FIG. 5. In this exemplary method, initialize operation at block 200. At the initialization stage, one unused block of memory is subsequently accessed. In block 202, suppress error-correction code errors or parity errors in the unused block of memory. Next, initialize the unused block of memory block 204. At this block, the memory controller 16 in accordance with one exemplary embodiment of the present invention refreshes the unused block of memory. Then, mark the unused block of memory as one of the used blocks of memory in block 206. At block 208, re-enable error correction codes or parity codes. Operational blocks 200-208 are performed for each unused block of memory that is subsequently accessed. Further, the operations in blocks 200-208 can be performed during the operation in blocks 100-108 in FIG. 4 in accordance with one exemplary embodiment.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for reducing power consumption in integrated devices, the method comprising:
locating a plurality of unused blocks of memory and a plurality of used blocks of memory in a memory device through a tracking mechanism;
performing a refresh operation on the plurality of used blocks of memory at a constant frequency and suppressing the refresh operation on the plurality of unused blocks of memory through a memory controller; and
suppressing error correction codes or parity errors on at least one of the plurality of unused blocks of memory when the at least one of the plurality of unused blocks of memory is accessed through the memory controller.

2. The method as in claim 1, further comprising:
initializing the at least one of the plurality of unused blocks of memory being accessed through the memory controller by performing the refresh operation on the at least one of the plurality of unused blocks of memory being accessed; and
marking the at least one of the plurality of unused blocks of memory being accessed as one of the plurality of used blocks of memory through the memory controller.

3. The method as in claim 2, further comprising enabling error correction codes or parity errors on the at least one of the plurality of blocks bits of memory through the memory controller.
